(19) United States
(12) Patent Application Publication
(10) Pub. No.: US 2006/0255353 A1
(43) Pub. Date: Nov. 16, 2006

(54) Light efficient packaging configurations for LED lamps using high refractive index encapsulants

(76) Inventors: Nikhil R. Taskar, Scaradale, NY (US); Vipin Chabra, Ossining, NY (US); Donald Dorman, Carmel, NY (US); Samuel P. Herko, Ossining, NY (US)

Correspondence Address: William L. Botjer, PO Box 478, Center Moriches, NY, 11934, US

(21) Appl. No.: 11/369,481

(22) Filed: Mar. 7, 2006

Related U.S. Application Data
(63) Continuation of application No. PCT/US04/29201, filed on Sep. 8, 2004.
(60) Provisional application No. 60/501,147, filed on Sep. 8, 2003.
(60) Provisional application No. 60/524,529, filed on Nov. 24, 2003.

(51) Int. Cl. H01L 33/00

(52) U.S. Cl. 257/98

(57) ABSTRACT

Light efficient packaging configurations for LED lamps using high refractive index encapsulants. The packaging configurations including dome (bullet) shaped LED's, SMD (surface mount device) LED's and a hybrid LED type, including a dome mounted within a SMD package. In another embodiment used with SMD LED devices a relatively small semi-hemispherical “blob” of HRI encapsulant surrounds the LED chip with the remainder of the SMD cavity filled with conventional encapsulant. The packaging configurations increase the LED's light emission efficiency at a reasonable cost and in a commercially viable manner, by maximizing the light efficiency while minimizing the amount of high refractive index encapsulant used.

### REFERENCE TO RELATED APPLICATIONS

This application is a continuation in part of PCT application PCT/US2004/029201 which in turn claims the priority of U.S. Provisional patent application Ser. No. 60/501,147 filed Sep. 8, 2003 and U.S. Provisional patent application Ser. No. 60/524,529 filed Nov. 24, 2003.

### BACKGROUND OF THE INVENTION

This invention relates to Light Emitting devices (LED's) and configurations suitable for increasing their light emission efficiency at a reasonable cost and in a commercially viable manner. More specifically this application relates to LED lamps using high refractive index encapsulants in various packaging configurations including dome (bullet) shaped, Top-Emitting SMD (surface mount device) and a hybrid type, including a dome mounted within a SMD package.

Typically, a LED lamp with a dome-shaped lens has a higher optical efficiency or Light Extraction Efficiency (LEE) than one without a dome. Hence, domed LED's have a higher Wall Plug Efficiency (WPE) and light output by as much 60% compared to a wide-angle emitting Top-Emitting SMD (Surface Mounted Device) lamp (without a dome-shaped lens). The Dome-shaped lens also imparts a more directional nature to the emission, and the angular spread of the beam is between 30 degrees to 90 degrees, compared to 120 degrees for a wide-angle emitting Top-Emitting SMD lamp.

Conventional dome shaped LED's include a number of components: 1) An LED die/chip with dimensions ranging from 0.2 mm to 0.3 mm for a low-power lamp, and from 0.5 mm to 2 mm for a high-power lamp. 2) A Reflective Cavity, formed in a substrate for an SMD lamp or in a lead-frame for a through-hole lamp, and having dimensions ranging from 1 mm to 5 mm diameter depending on the LED die/chip size (and lamp power). 3) Particularly in the case of a SMD lamp with a Dome-shaped lens, a pre-molded lens with a convex-shaped outer surface is mounted over the substrate, covering the reflective cavity. Typically, the pre-molded lens has a refractive index (RI) of ˜1.5. The outer diameter of the lens ranges from 5 mm to 10 mm. This modular assembly approach simplifies the lamp fabrication process. In a through-hole lamp, the Dome-shaped lens with 3 mm to 10 mm outer diameter fabricated from a conventional transparent encapsulant with an RI˜1.5 is directly molded over the reflective cup containing the LED die/chip and in certain cases the reflective cup is filled with a partially cured silicone encapsulating the die/chip, prior to molding the lens. 4) In a SMD lamp with a dome-shaped lens, the space or gap between the inner surface of the lens and the reflective cavity containing the LED die/chip is filled with a transparent optical gel with an RI between 1.5 to 1.7 for efficient optical coupling between the die/chip and the lens. Particularly in high-power lamps, the pliable encapsulating gel also prevents mechanical stress due to a difference in the thermal expansion coefficient of the large sized die/chip, lens material and other subcomponents of the lamp, such as the reflective cavity and substrate.

It is known to those skilled in the art that replacing a conventional dome-shaped encapsulating lens with a RI=1.5, by a dome-shaped encapsulating lens with a RI=1.7 or higher (known as a High Refractive Index or HRI encapsulant) can enhance the WPE of a LED lamp by 20% to 45% depending on details of the LED chip/die material and geometry. However such HRI encapsulants are relatively expensive when compared to standard RI=1.5 encapsulants. The cost disadvantage is exacerbated by the fact that LED's are designed to be produced in the millions and sold for a few to tens of pennies. A cost effective means for increasing the light emission efficiency of LED's at a reasonable cost and in a commercially viable manner is thus desired in the art.

This invention also relates to Surface Mount Device (SMD) Light Emitting Diode (LED) lamps which represent the fastest growing segment in the LED market, spanning both monochrome and white-LED lamps. The reasons for the widespread adoption of SMD packaging configurations are as follows: The compatibility of SMD package with surface-mount assembly techniques for circuit boards and it's relatively smaller form factor (˜3 mm×3 mm×2 mm to 10 mm×10 mm×3 mm) An electrode Layout compatible with Wave-Soldering and Pick-and-Place automated tools. The wider angular spread of the optical beam for a Top-Emitting SMD (120 degrees, i.e 60 degrees on either side of the package optical axis) compared to Thru-Hole (60 degrees) which make it desirable for backlighting in displays and indicator applications. The Thru-Hole package has a convex shaped encapsulant lens (typically 5 mm sized) which is much larger than, and surrounding the metal cup, with a specularly reflective internal surface, housing the LED chip. The metal cup cavity is typically sized less than 2 mm in diameter.

In a low-power (0.1 W electrical input) SMD package the LED chip is housed in a thermoplastic cup with internal surfaces that are diffused reflectors with a white appearance. Also, the wide angle emitting Top-Emitting SMD package has a flat-topped encapsulant lens contained inside the cup. The cup cavity is typically sized about 2 mm to 2.5 mm in diameter and about 1 mm in height. The narrower angle emitting SMD package with ˜30% higher optical efficiency has a convex lens, but its diameter does not significantly exceed that of the cup cavity (unlike Thru-Hole applications). The flat-topped encapsulant lens results in a planar form factor for the package, that enables coupling of the Top-Emitting SMD LED lamp to a light-guide or an optical-relay device for light distribution in an illumination system. This is particularly desirable for the application in hand-held devices and automotive interior dashboard illumination.

In White-LED lamps based on Blue emitting die/chip, the diffused reflector enhances the mixing of the die/chip emission and phosphor-emission thereby enhancing color homogeneity. In monochrome lamps, a wide angle emitting Top-Emitting SMD package has a lower optical efficiency than the Thru-Hole package. Light Extraction Efficiency (LEE), hence the wall plug efficiency and light output, of the wide angle emitting Top-Emitting SMD lamp is typically between 60% to 65% of the corresponding value for a Thru-Hole 5 mm lamp based on the same LED chip. Thus, it is desirable to enhance the LEE of a wide angle emitting Top-Emitting SMD package.

The transparent encapsulants that surround the LED in SMD packages have an Refractive Index (RI) of about 1.5 which results in an RI mismatch with the LED which has a higher RI of approximately 2.5 to 3.5. Recently, substantially transparent encapsulant materials having refractive indexes of 1.7 or greater have been developed which substantially reduce the index mismatch between the LED and the encapsulant which increases the light extracted from the LED. The present invention utilizes these high IR (HRI) encapsulants with an improved geometry that provides improved light extraction while using less encapsulant material than prior configurations. The present invention is usable with any of the substantially transparent encapsulant materials having refractive indexes of 1.7 or greater. Suitable encapsulants are described in, for example, PCT patent application PCT/US05/40991 the disclosure of which is hereby incorporated by reference.

### SUMMARY OF THE INVENTION

The present invention has applicability to any generally transparent HRI encapsulants and is particularly applicable to HRI encapsulants utilizing dispersed non-agglomerated HRI nanoparticles disposed in a transparent matrix of lower RI encapsulant. The presence of the HRI nanoparticles serves to raise the RI of the composite encapsulant to 1.7 or greater. In addition to the refractive index raising nanoparticles the composite encapsulant may also include light emitting phosphors which will further increase and/or alter the color of the light output

A first embodiment of is directed to dome shaped configurations having the following components: An LED die/chip (with or without a submount). A reflective cavity containing the LED die/chip (diffuse or specular reflector). A high refractive index (HRI) material (with a refractive index greater than or equal to 1.7) encapsulating the LED die/chip and contained inside the reflective cavity (The shape of outer surface of the HRI encapsulant contained in the reflective cavity may be either concave, flat or convex). A dome-shaped lens with a RI smaller than that of the HRI encapsulant. The outer surface of the lens is convex in shape (i.e. the interface with the ambient), whereas the inner surface (facing the LED die/chip) may be either planar, concave or convex. An optical gel material with a RI smaller than that of the HRI encapsulant but at least equal to that of the lens, is disposed in the space/gap between the HRI encapsulant and the inner surface of the dome-shaped lens. In certain applications the optical gel material may be omitted The HRI encapsulant may optionally contain a fluorescent material to obtain lamp emission at wavelengths different from those comprising the LED die/chip emission.

One variant of the first embodiment of the present invention uses a SMD lamp mounted in a dome, wherein the reflective cavity containing the die/chip is filled with an HRI encapsulant, prior to placing a pre-molded dome-shaped lens with a RI=1.5 (lower than the RI of the HRI encapsulant) over the substrate and covering the reflective cavity. The shape of outer surface of the HRI encapsulant contained in the reflective cavity may be either concave, flat or convex. This is followed by filling the gap between the HRI encapsulant and the inner surface of the dome-shaped lens and/or between the lens and the substrate, with an optical gel with a RI between 1.5 to 1.7 (lower than the RI of the HRI encapsulant but at least equal to that of the lens). Another variant of the first embodiment of the present invention is directed to through-hole lamps, wherein the reflective cavity containing the die/chip is filled with HRI encapsulant, followed by directly molding a conventional encapsulant based dome-shaped lens over it. The shape of outer surface of the HRI encapsulant contained in the reflective cavity may be either concave, flat or convex.

The present invention provides a number of advantages: The optical efficiency and WPE of the proposed LED lamp is higher than that of a LED lamp without the HRI encapsulant, depending on the chip/die material and geometry. The proposed LED lamp uses at least an order of magnitude lower amount of the HRI material (hence a lower material cost and a lower weight of the lamp) compared to a LED lamp whose entire dome-shaped encapsulant lens is fabricated from HRI material. The WPE of the proposed LED lamp is relatively independent of the shape of the outer surface of the HRI encapsulant contained inside the reflective cavity, which makes it a more robust design in a production environment. The proposed LED lamp also avoids any fabrication and reliability challenges that are posed by the HRI material having lower mechanical and structural strength compared to a conventional encapsulant, which could also create problems with molding the dome-shaped lens. The proposed LED lamp also minimizes any WPE performance penalty that may arise if the HRI material exhibits optical absorption at the LED lamp emission wavelengths (due to the shorter optical path length for the emission in the HRI material in the present invention, compared to wherein the entire dome-shaped encapsulant lens is fabricated from the HRI material).

A second embodiment of the present invention provides an improved configuration for the encapsulants used in Top-Emitting SMD LED packages. The invention uses High Refractive Index (HRI) encapsulants having a refractive index of approximately 1.7 or greater. The HRI encapsulant is used in place of the standard transparent encapsulant which has a refractive index of about 1.5, it has been found that the optimum configuration for the encapsulant is to provide a concave upper surface rather than the flat or convex surfaces that have been used to date. The concave HRI encapsulant configuration provides a greater light extraction efficiency while at the same time using less encapsulant material than the conventional flat or convex surfaced encapsulants. The encapsulant configuration of the present invention can be achieved without making any changes to the standard Top-Emitting SMD LED chip package. The concave HRI encapsulant or lens may also be used in many other lighting applications where maximum light extraction with minimum material is desired.

The attributes of this embodiment include: A Top-Emitting SMD LED lamp with concave shaped lens with high refractive index which may be used with an LED die/chip that emits either monochromatic or broad-band emission. The encapsulant may contain fluorescent material that emits wavelengths complementary to those emitted by die/chip, upon excitation by die/chip emission, so as to further increase the luminous output and luminous efficacy. The sidewall of the SMD cup may be either a diffusive reflector or a specular reflector.

The second embodiment of the present invention provides monochrome Top-Emitting SMD LED lamps with a diffusively reflective sidewall, which experience between 20% to 35% LEE enhancement using RI=1.7 or greater concave lens compared to RI=1.5 flat-top lens. Monochrome Top-Emitting SMD LED lamps with a specularly reflective sidewall, which experience >85% LEE enhancement using HRI concave lenses compared to RI=1.5 flat-top lenses. Monochrome Top-Emitting SMD LED lamps with a specularly reflective sidewall, experience >45% LEE enhancement using a HRI=1.8 concave lens compared to RI=1.5 concave lens. This is achieved while using a minimal amount of the relatively costly HRI encapsulant.

In a further “hybrid” embodiment a small “mini-dome” is disposed on the concave surface of the Top-Emitting SMD package over the LED chip. In this configuration the lamp acquires a narrower angular emission, resulting in a higher enhancement of the on-axis brightness. This enables the achievement of higher brightness lamps for applications that require narrower angular emission characteristics, while simultaneously providing a “Flat-Profile” form-factor.

In another embodiment used with SMD LED devices a relatively small semi-hemispherical “blob” of HRI encapsulant surrounds the LED chip with the remainder of the SMD cavity filled with conventional encapsulant. This provides maximum light extraction from the LED chip with a minimum amount of HRI encapsulant.

### BRIEF DESCRIPTION OF THE DRAWINGS

For a better understanding of the invention, reference is made to the following drawings which are to be taken in conjunction with the detailed description to follow in which:

FIG. 1 of the drawings illustrates the components of a high efficiency LED device in accordance with the present invention and the lighting efficiency performance provided thereby;

FIG. 2 of the drawings is similar to that of FIG. 1 but wherein the LED emits blue light and the encapsulant includes yellow emitting phosphors;

FIGS. 3, 4 and 5 of the drawings illustrate various dome type configurations for LED packages in accordance with the present invention;

FIG. 6 of the drawings through 10 illustrate further dome type configurations for LED packages in accordance with the present invention with various refractive index components;

FIGS. 11 and 12 of the drawings illustrate the configurations of the SMD type packaging in accordance with the present invention;

FIG. 13 of the drawings is similar to FIGS. 11 and 12 and shows the normalized LEE values for a diffusive reflective sidewall along with the values for specularly reflective sidewall;

FIG. 14 of the drawings illustrates a hybrid embodiment of the present invention in a which a “mini-dome” is disposed at the center of the concave lens of the SMD LED device.

FIG. 15 is a sectional view of a SMD chip embodiment with a HRI encapsulant “Blob” with a semi-hemispherical form-factor; and

FIGS. 16 and 17 of the drawings illustrate various semi-hemispherical “Blob” configurations of the SMD type packaging in accordance with the present invention.

### DESCRIPTION OF THE PREFERRED EMBODIMENTS

Dome Shaped Configuration

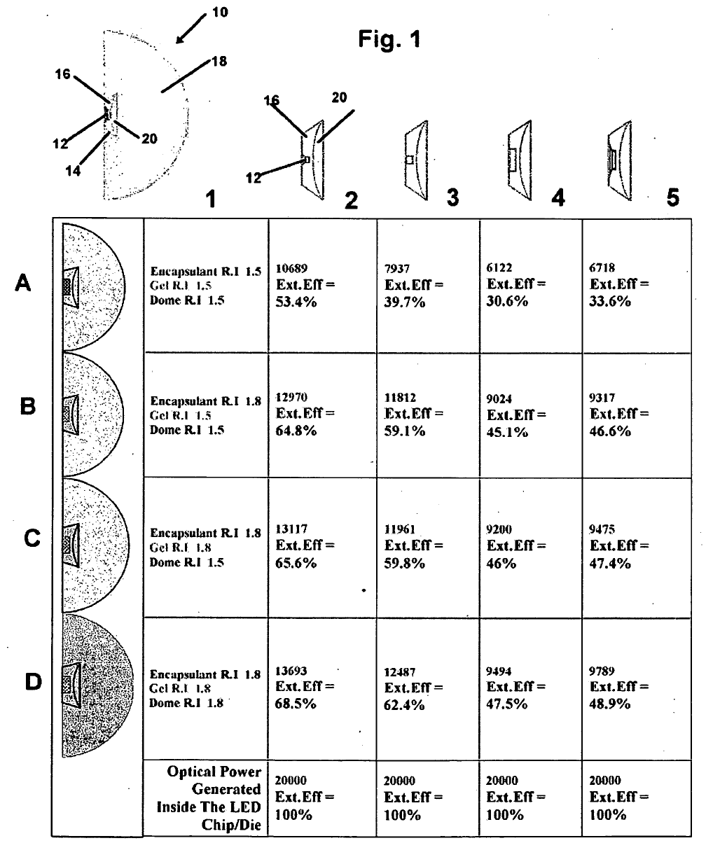

FIG. 1 of the drawings shows the components of a high efficiency LED device 10 in accordance with the present invention and the improved performance provided thereby. Device 10 includes an LED die/chip 12 mounted within a reflective cavity 14 which may be a diffuse or a specular reflector. A transparent high refractive index (HRI) material 16, with a refractive index greater than or equal to 1.7 (modeled in the tables to follow as having an RI=1.8), encapsulates LED die/chip 12 and is contained inside reflective cavity 14 The shape of the outer surface of HRI encapsulant 16 contained in the reflective cavity may be either concave, flat or convex. A dome-shaped lens 18 with a RI smaller than that of the HRI encapsulant surrounds reflective cavity 14. The outer surface of lens 18 is convex in shape, whereas its inner surface (facing the LED die/chip) may be either planar, concave or convex. A transparent optical gel material 20 with a RI smaller than that of HRI encapsulant 16 but at least equal to that of lens 18, is filled in the space or gap between HRI encapsulant 16 and the inner surface of dome-shaped lens 18. HRI encapsulant 16 may optionally contain a fluorescent material to obtain lamp emission at wavelengths different from those comprising LED die/chip 12's emission.

The table of FIG. 1 illustrates various configurations of LED die/chip 12 shown in columns 2-5 with various refractive index components of encapsulant 16, optical gel 20 and dome 18 shown in rows A through D with the RI values listed in column 1. Each block of FIG. 1 shows the LEE (called Ext. Eff, in %) and optical power (in arbitrary units) obtained from ray-tracing simulations, for a variety of LED chip/die geometries. The current state of the art is shown in row A. (RI=1.5 encapsulant, RI=1.5 optical gel, RI=1.5 dome) The present invention is shown in row B—where the outer surface of the HRI encapsulant contained inside the reflective cavity is concave. (RI=1.8 encapsulant, RI=1.5 optical gel, RI=1.5 dome). Another embodiment of the present invention is shown in row C—(RI=1.8 encapsulant, RI=1.8 optical gel, RI=1.5 dome) which is similar to a configuration where the outer surface of the encapsulant contained inside the reflective cavity is flat. An extension of the present invention in row D—where the entire dome is also fabricated from HRI material. (RI=1.8 encapsulant, RI=1.8 optical gel, RI=1.8 dome). The optical power generated inside the LED chip/die was set at 20000 arbitrary units, for these simulations (and corresponds to a LEE of 100%). In the drawing corresponding to each case, the RI=1.8 material is represented by a darker shade compared to the RI=1.5 material.

Using the cubical configuration of LED 12 shown in column 3 as an example it is seen at row A with a RI=1.5 encapsulant, a RI=1.5 optical gel, and a RI=1.5 dome the LEE was 39.7%. In row B with a RI=1.8 encapsulant, a RI=1.5 optical gel, and a RI=1.5 dome the LEE increased to 59.1% an increase of over 19% over the configuration with a RI=1.5 encapsulant. In row C with a RI=1.8 encapsulant, a RI=1.8 optical gel, and a RI=1.5 dome the LEE increased to 59.8% an increase of less than 1% over the Row B configuration. In row D with a RI=1.8 encapsulant, optical gel, and dome the LEE increased to 62.4% an increase of less than 3% over the Row C configuration even though all encapsulant, gel and dome used the relatively expensive HRI material. While the percentages in the other LED configurations vary the overall results are clear: the percentage increase of LEE is greatest when the encapsulant has a RI=1.8 rather than 1.5 and that the percentage increase when using HRI for the gel and dome are similar. This means that LED devices using a HRI encapsulant but with non HRI gels and dome can be very cost effective while providing high efficiency.

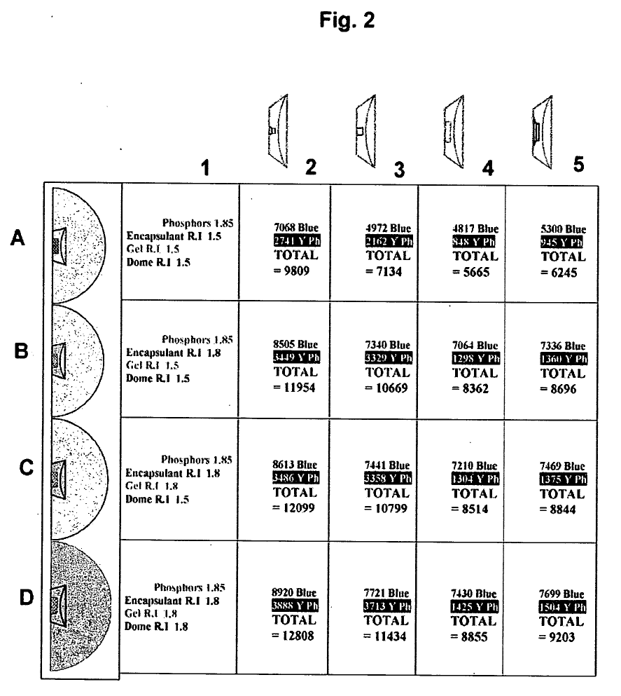

FIG. 2 is laid out similar to that of FIG. 1 but wherein the LED emits blue light and the encapsulant includes yellow emitting phosphors having a RI of about 1.85. This arrangement forms a “white” light emitting LED when the blue of the LED is mixed with the yellow emitted by the phosphors FIG. 2 shows the optical power (in arbitrary units) at both the LED chip/die emission wavelength (Blue) and the downconverted phosphor emission wavelength (Yellow: Y Ph), obtained from ray-tracing simulations for a variety of LED chip/die geometries (columns 2-5). The current state of the art shown in row A. (RI=1.5 encapsulant, RI=1.5 optical gel, RI=1.5 dome). The present invention shown in row B—where the outer surface of the HRI encapsulant contained inside the reflective cavity is concave. (RI=1.8 encapsulant, RI=1.5 optical gel, RI=1.5 dome) Another embodiment of the present invention is shown in row C—(RI=1.8 encapsulant, RI=1.8 optical gel, RI=1.5 dome) which is similar to a configuration where the outer surface of the encapsulant contained inside the reflective cavity is flat.

Bulk phosphor with a RI=1.85, that absorbs the Blue wavelength emitted by the LED chip/die and emits Yellow wavelength (such as YAG:Ce) is embedded in the encapsulant surrounding the chip/die. The volume concentration and spatial distribution profile of the phosphor was identical in each of the 4 lamp cases corresponding to a specific LED chip/die geometry. Thus, these results correspond to a specific volume concentration and spatial distribution profile of the phosphor. The optical power generated inside the LED chip/die was 20000 arbitrary units at the Blue wavelength, for these simulations. In the schematic corresponding to each case, the RI=1.8 material is represented by a darker shade compared to the RI=1.5 material The efficiency results of the configurations of FIG. 2 are similar to that of FIG. 1: a meaningful increase in LEE is achieved when the RI of the encapsulant is changed from 1.5 to 1.8 while the increases are less when the gel and the dome are also changed from 1.5 to 1.8.

It should be noted that the ratio of the optical power at the Blue wavelength to that at the Yellow wavelength (B/Y) monotonically decreases from configurations A through D. Thus, the chromaticity coordinate (ie. color) of the emission is different in each case and this variation can be prevented by appropriately adjusting the phosphor concentration in each case to obtain an identical value for B/Y. A smaller B/Y ratio corresponds to a relatively higher contribution to the optical power from the Yellow spectral regime compared to the Blue spectral regime. Thus a smaller B/Y ratio corresponds to a higher luminous equivalent value (ie. lumens per watt of total optical power emitted by the lamp) due to 70 lm/W @ 470 nm vs 680 lm/W @ 550 nm. This implies that the luminous efficacy enhancement between configuration A and configurations B and C (similarly between configurations B, C and case D), would tend to be slightly greater (by less than or equal to ˜4%) than the WPE enhancement which is indicated by the ratio of the total optical power for each case. It should also be noted that the WPE of the monochrome LED is always greater than that of the corresponding phosphor containing White-LED based on an identical chip/die and lamp geometry (by comparing FIGS. 1 and 2 for configurations A through D of any specific chip/die).

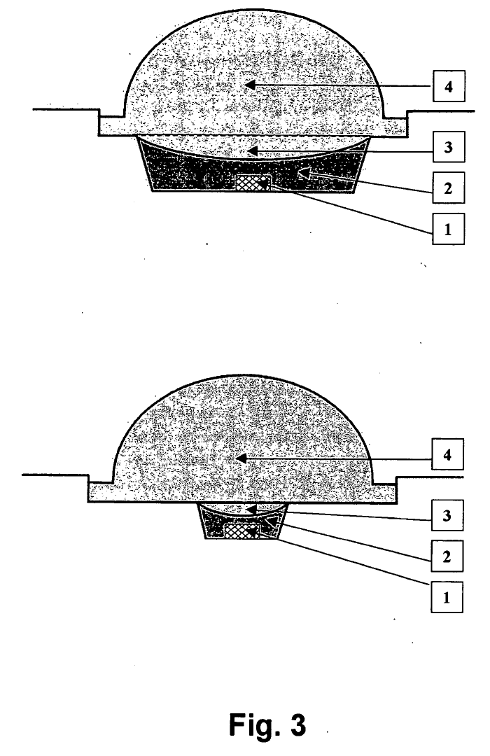

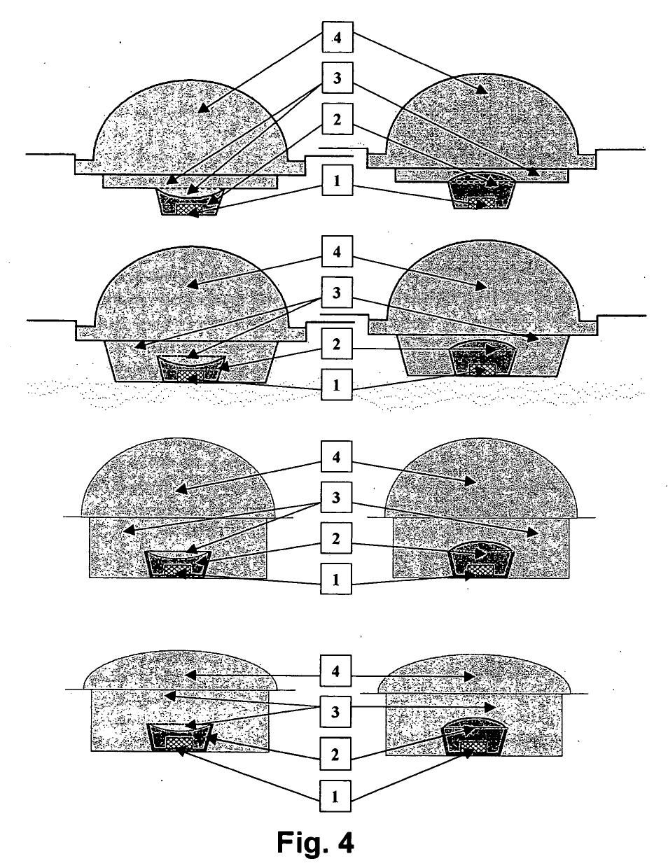

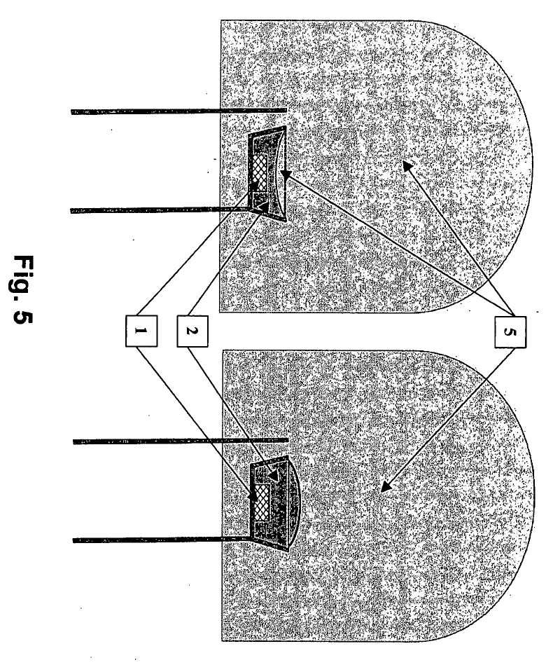

FIGS. 3, 4 and 5 illustrate various configurations for LED packages in accordance with the present invention. In these drawings reference number 1 is an LED chip/die, reference number 2 is an HRI encapsulant disposed within a reflective cavity, reference number 3 is an optical gel with a refractive index smaller than that of the encapsulant, reference number 4 is a pre-molded dome shaped lens covering the reflective cavity and reference number 5 (in FIG. 5) is a molded dome shaped lens molded around and encapsulating the reflective cavity and its attached lead wires.

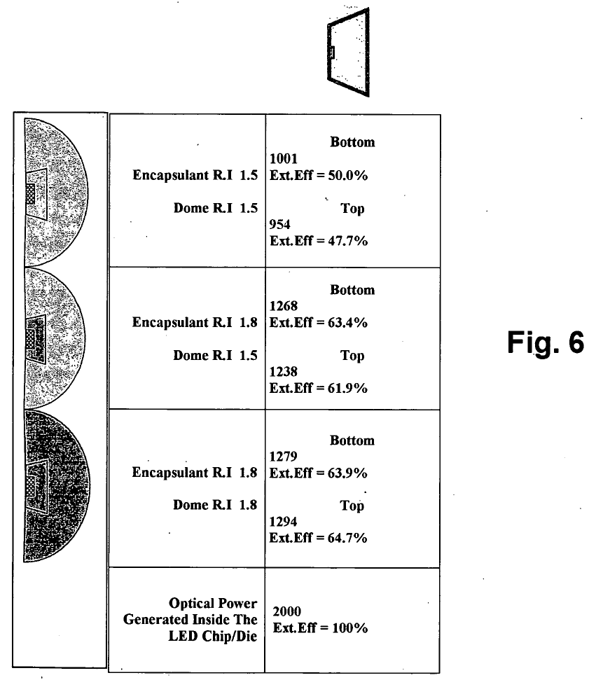

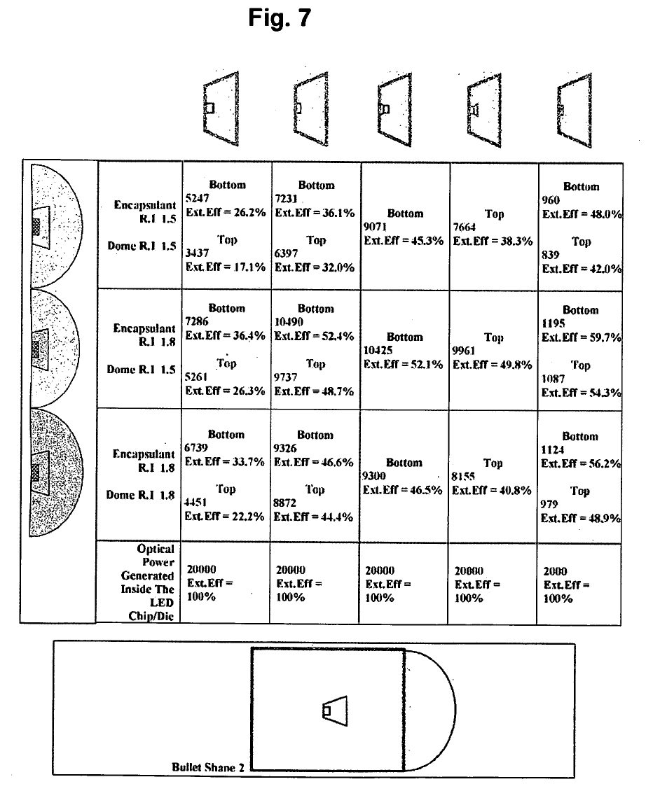

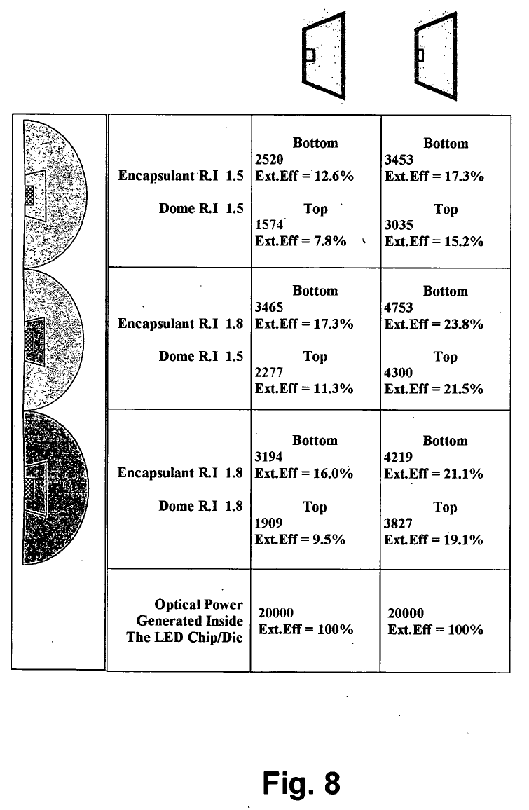

FIGS. 6 through 10 illustrate various other configurations for LED packages in accordance with the present invention with various refractive index components. FIG. 6 shows the light extraction efficiency of various encapsulant and dome configurations used with a sapphire LED chip mounted in both a top and a bottom emitting configurations and without the use of optical gel. FIG. 7 shows the light extraction efficiency of a “bullet” shaped device in which the chip, reflecting cavity are enclosed in a cylinder of hard transparent epoxy and a generally hemispherical lens (dome) at one end used with an LED chip having a RI=2.5 mounted in both top and a bottom emitting configurations. FIG. 8 is the same device as that of FIG. 7 except the LED has a RI of 3.5. FIG. 9 shows the light extraction efficiency of a second type of “bullet” shaped device in which the chip, reflecting cavity are enclosed in a cylinder of hard transparent epoxy and a generally smaller (less convex) lens (dome) than that of FIG. 7 used with an LED chip having a RI=2.5 mounted in both top and a bottom emitting configurations. FIG. 10 is the same device as that of FIG. 9 except the LED has a RI of 3.5.

In each of the configurations of FIGS. 6-10 it is seen that the use of HRI encapsulating material provides a significant increase in light output over a standard RI=1.5 encapsulant. The use of a HRI dome or lens provides a further increase in light output but the increase is smaller and in many instances may not be cost effective.

Top-Emitting SMD Configuration

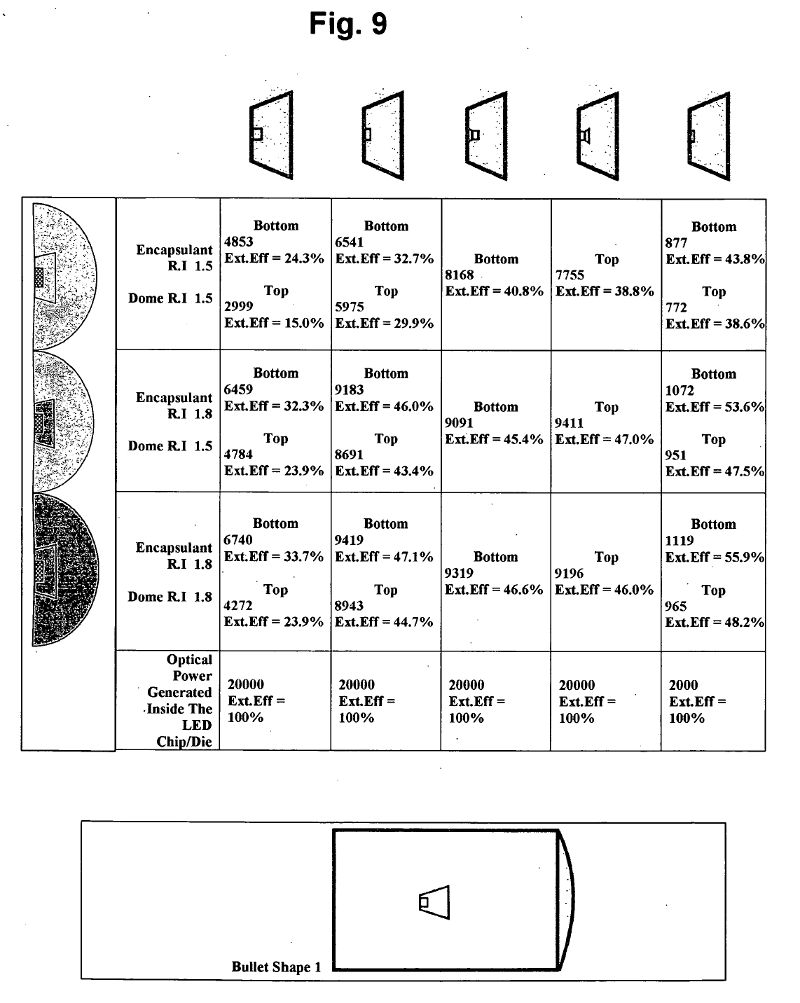

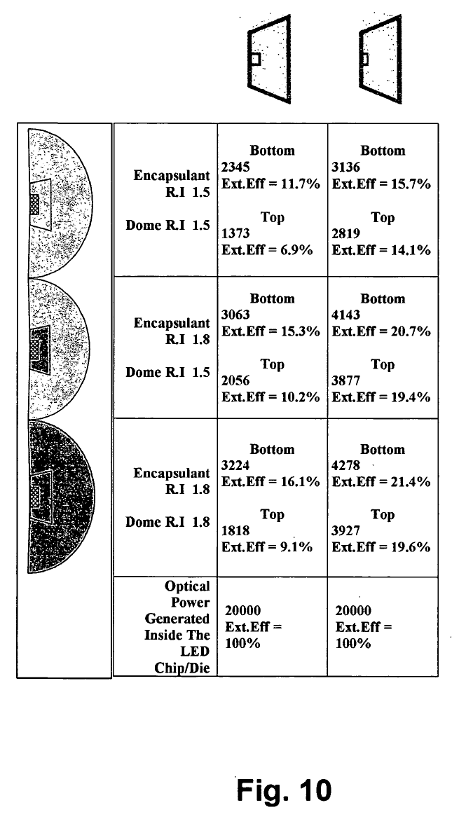

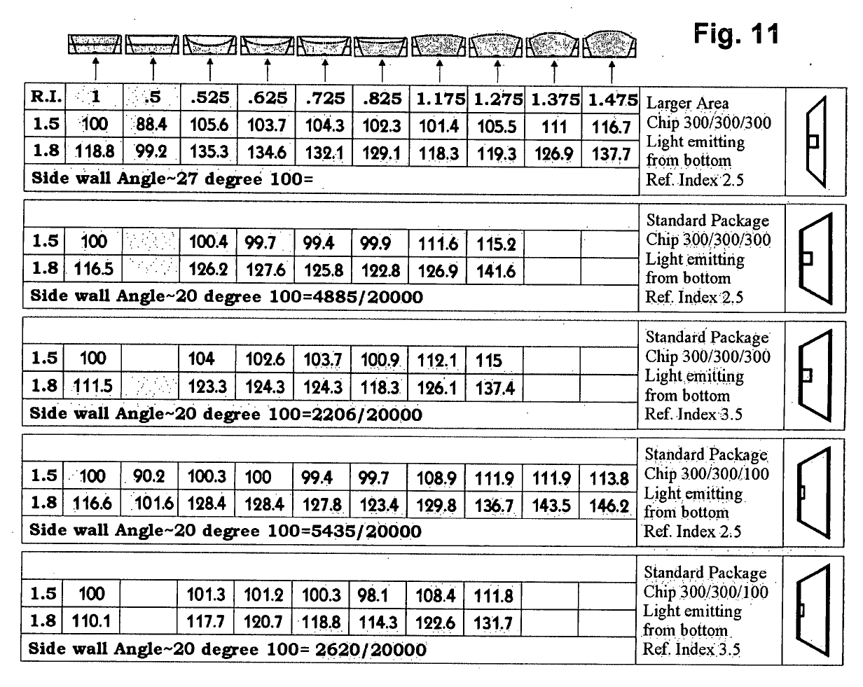

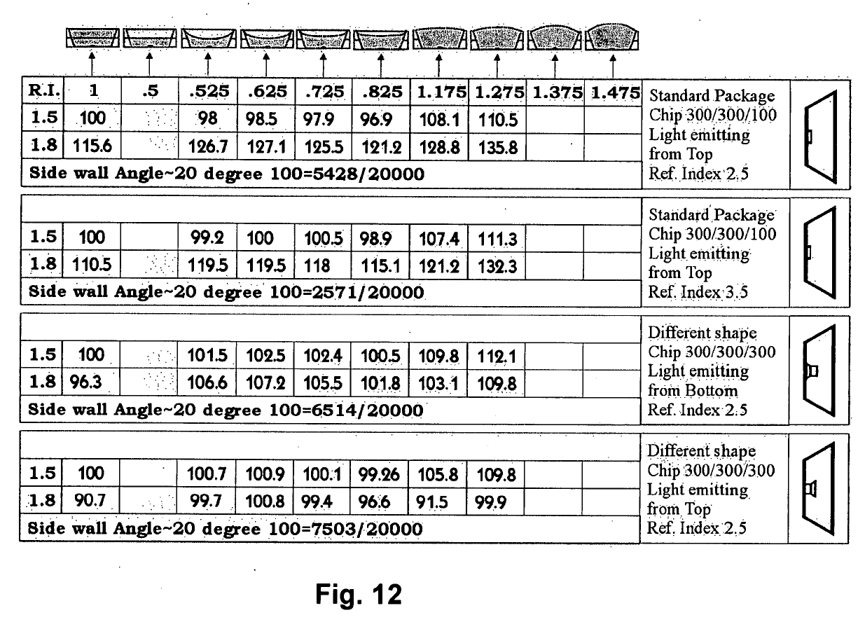

FIGS. 11 and 12 illustrate the configurations of the Top-Emitting SMD type packaging which have been modeled. These configurations do not use an external dome. The upper row shows 10 configurations from flat topped (The first 2 examples); various degrees of concavity (third through sixth examples) and various degrees of convexity (seventh through tenth examples). the numbers in the first row are the center height (in mm) of each configuration, measured from the bottom of the standard Top-Emitting SMD package which is approximately 2.8 by 3.1 mm and having a circular 2.5 mm hole at the bottom in which the LED chip is mounted. The LED can be mounted with the light emitting from the top (called EPI up) or the bottom (EPI down). The left hand column depicts the refractive index (R.I.) of the encapsulants that have been modeled either the standard 1.5 RI epoxy or the 1.8 RI HRI encapsulant. The numbers in the rows next to the encapsulant refer to the modeled light intensity with the standard 1 mm 1.5 RI flat topped encapsulate set at 100 so that a number higher than 100 indicates greater light emission while a number lower than 100 indicates lesser light emission than the standard. The right hand column is a schematic representation of the Top-Emitting SMD package and LED chip, the text next to the right hand column describes the size of the SMD package, the size of the LED chip (in microns), the orientation of the light emitted by the chip and the refractive index of the chip. The horizontal line of text describes the sidewall angle of the reflector and the intensity of the 100 reference intensity (in arbitrary units)

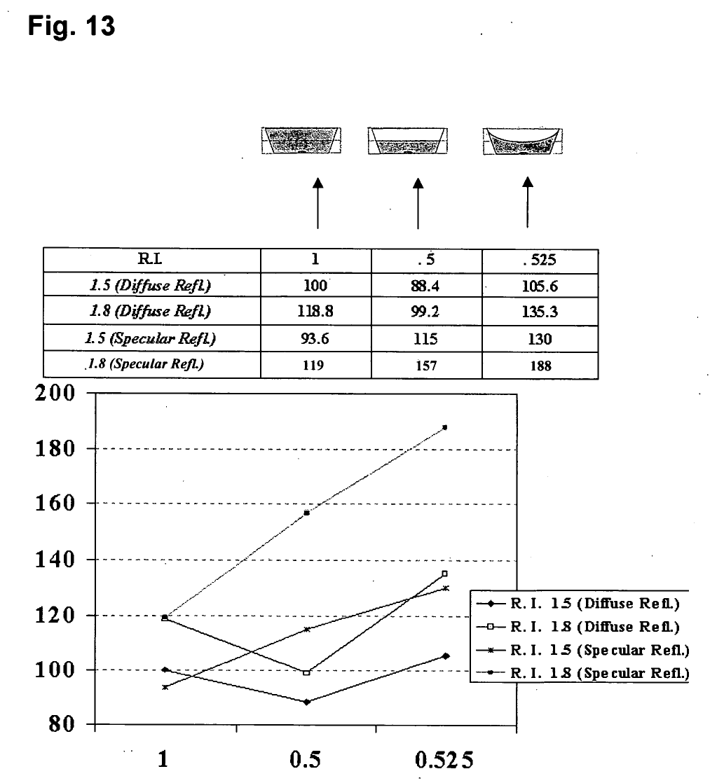

FIGS. 11 and 12 show the dependence of normalized LEE value on the RI and form-factor of the Top-Emitting SMD lamp package encapsulant lens, for monochrome AlInGaN (RI=2.5) and AlInGaP (RI=3.5) die/chip geometries. FIG. 13 is similar to FIGS. 11 and 12 and shows the normalized LEE values for a diffusive reflective sidewall along with the values for specularly reflective sidewall. it is seen that: for RI=1.5, changing the lens shape from flat-top (1 mm thick) to concave with ˜0.6 mm depth (but 1 mm thick at periphery) increases LEE by only ˜5% in the best case. Hence, it is not effective to use a concave SMD lens for conventional encapsulants. A SMD lamp with RI=1.5 flat-top lens and a diffusive reflective sidewall, is used as the reference herein. 2) The RI=1.8 flat-top lens, increases the LEE by ˜10% to 15% compared to RI=1.5 flat-top lens. In contrast, Thru-Hole LED lamps experience a 55% to 60% increase in LEE upon increasing the RI from 1.5 to 1.8. The flat-top makes it relatively harder to extract light from the package into air, despite the higher light extraction from the die/chip into the package with increased RI of the encapsulant. The Thru-Hole has a hemispherical dome shaped lens. The RI=1.8 concave lens with ˜0.6 mm depth (but 1 mm thick at periphery) increases LEE by ˜20% to 30% compared to RI=1.5 flat-top lens.

A Top-Emitting SMD package with a specularly reflective cup sidewall, an RI=1.5 flat-top lens, decreases LEE by ˜5% compared to the reference. Accordingly, it is not effective to use a specularly reflective sidewall with a flat-top lens. A Top-Emitting SMD package with a specularly reflective cup sidewall, RI=1.5 concave lens with ˜0.6 mm depth (but 1 mm thick at periphery), increases LEE by 30% compared to the reference. 6) A Top-Emitting SMD package with a specularly reflective cup sidewall, RI=1.8 flat-top lens, increases LEE by 19% compared to the reference. A Top-Emitting SMD package with a specularly reflective cup sidewall, RI=1.8 concave lens with 0.5 mm depth (but 1 mm thick at periphery), increases light output by 88% compared to the reference. This is a 45% enhancement compared to a similarly shaped RI=1.5 encapsulant lens.

A plot of the angular dependence of the emission intensity from monochrome AlInGaN (RI=2.5) Top-Emitting SMD lamps with a concave RI=1.8 lens and a flat-top RI=1.5 lens, respectively (diffusively reflective sidewall) show a uniform angular dispersion of light with concave HRI lens which compares favorably to that of the flat 1.5 RI. A plot of the angular dependence of the emission intensity from the monochrome AlInGaP (RI=3.5) Top-Emitting SMD lamp with a concave RI=1.8 lens (diffusively reflective sidewall) also shows a uniform angular dispersion of light with concave HRI lens. The Top-Emitting SMD lamp with a concave RI=1.8 lens retains the desirable wide angle emission attribute of the conventional Top-Emitting SMD lamp with a flat-top RI=1.5 lens. Both the AlInGaN and AlInGaP die/chip based Top-Emitting SMD lamps exhibit an intensity value that is one-half of the peak intensity at an angular location whose separation is greater than 60 degrees (Angle value <30) from the optical-axis of the lamp package (Angle value =90), similar to that for a conventional Top-Emitting SMD lamp. For the concave RI=1.8 lens, the absolute peak intensity value occurs at an angular location separated by ˜20 degrees from the optical axis (rather than along the optical axis). However, the difference between the peak intensity value and the corresponding value along the optical axis is only ˜5% and ˜10% for the AlInGaN and the AlInGaP die/chip, respectively. This angular displacement of the intensity peak position with respect to the optical axis is a consequence of the concave shaped lens, and is also observed for a concave RI=11.5 lens. It is seen that a concave lens provides greater light output than a convex lens while using less HRI material.

Monochrome AlInGaP Red and Yellow Top-Emitting SMD LED lamps with High Refractive Index (HRI) encapsulant concave lenses have been fabricated with the degree of concave curvature varied (i.e. the depth of the lens or encapsulant thickness in the center while maintaining a fixed but larger thickness of the encapsulant at the periphery). We have observed a ˜20% enhancement in LEE of the Red and Yellow Top-Emitting SMD LED lamps by using a concave RI˜1.8 encapsulant lens compared to a conventional RI=1.5 flat-top encapsulant lens.

Monochrome AlInGaN Green Top-Emitting SMD LED lamps with High Refractive Index (HRI) encapsulant concave lenses have been fabricated with the degree of concave curvature varied (i.e. the depth of the lens or encapsulant thickness in the center while maintaining a fixed but larger thickness of the encapsulant at the periphery). We have observed a 20% to 25% enhancement in LEE of the Green Top-Emitting SMD LED lamps by using a concave RI˜1.8 encapsulant lens compared to a conventional RI=1.5 flat-top encapsulant lens.

Ray-tracing simulations for Top-Emitting SMD White-LED lamps with an “optically non-scattering downconverter” using conventional phosphor and HRI encapsulant indicate that the WPE (Wall Plug Efficiency) and light output (including the contribution to the optical power from both the downconverted emission from the phosphor and the non-downconverted die/chip emission) of the Top-Emitting SMD White-LED lamps is enhanced by greater than 20% to 30%, depending on details of the spatial distribution of the phosphor (ie. phosphor concentration localized in vicinity of the die/chip or phosphor concentration uniformly distributed in the encapsulant), by using a concave RI˜1.8 encapsulant lens compared to a conventional RI=1.5 flat-top encapsulant lens. Increasing the degree of concave curvature (by decreasing the encapsulant thickness in center) of the RI˜1.8 encapsulant lens enhances the WPE and light output. Top-Emitting SMD White-LED lamps with an “optically non-scattering downconverter” using conventional phosphors and HRI encapsulant, are currently being fabricated with a concave lens. Since the Top-Emitting SMD White-LED lamps are based on an AlInGaN Blue LED die/chip, it is likely that improvement in optical transparency of the HRI in the Blue spectral regime will result in an enhancement of the luminous efficacy compared to the conventional Top-Emitting SMD White-LED lamp with a flat-top lens.

We have observed that HRI based Top-Emitting SMD White-LED lamps with an “optically non-scattering downconverter” and a specularly reflective sidewall, exhibit at least 40% higher optical power compared to the conventional encapsulant based lamps, for similar color of white-light emission. Thus at least 40% improved WPE of a Top-Emitting SMD White-LED lamp, results from the use of the HRI encapsulant compared to the conventional encapsulant with the same LED and phosphor. The physical properties of the HRI (viscosity, adhesion to cup sidewall, surface tension) facilitate the attainment of a concave shaped interface with air, compared to a conventional epoxy. Thus by regulating the volume of HRI dispensed in the cup (controlled by varying its dilution with a solvent that can evaporate and filling the cup), we are able to vary the extent of concave curvature. Increased concave curvature being characterized by a smaller value of the ratio of the encapsulant thickness in the center to that at the cup periphery along the sidewall. HRI exhibits an extremely high degree of adhesion to the cup sidewall surface. Hence the encapsulant thickness at the periphery of the cup always corresponds to the depth of the cup (1 mm) even after the solvent evaporates and the thickness monotonically decreases towards the center of the cup, yielding a concave shape.

Hybrid Embodiment

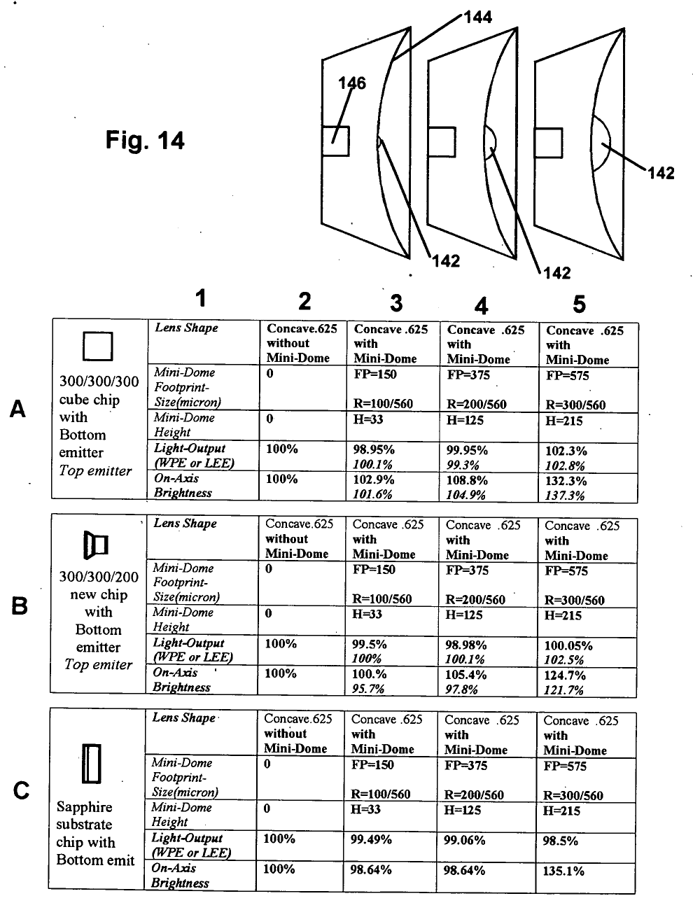

FIG. 14 illustrates a hybrid embodiment of the present invention in a which a “mini-dome” 142 is disposed at the center of the concave lens 144 of the Top-Emitting SMD device as discussed above in FIGS. 11-13. The diameter (“footprint”) of the mini-dome 142 is between 100 to 1000 microns and is typically on the order dimension of the die/chip 146. The height of the mini-dome 142 is such that it does not protrude above the rim of the package (thus maintaining its form-factor) and is typically on the order of several 100 microns.

The table of FIG. 14 illustrates various configurations of LED die/chip 146 shown in rows A-C with various sizes of mini-domes 142 shown in columns 3-5. Column 1 lists the dimensions of the mini-dome: FP=footprint (diameter), R=radius of curvature of the spherical mini-dome/position of center of curvature of the mini-dome above bottom of the package, H=height of the mini-dome above the concave lens, the light output (LEE or WPE) and the on axis brightness obtained from ray-tracing simulations, for a variety of LED chip/die geometries. Column 2 shows a concave Top-Emitting SMD without a mini-dome having an encapsulant thickness of 0.625 mm in center, which is also shown in FIG. 11 and which is used as “standard”. Row A shows a 300 micron cubical chip with either top or bottom emission (with the light output and brightness shown in italics for the top emitter and non-italics for a bottom emitter). Row B shows a 300/300/200 micron trapezoidal “new” (geometrically enhanced shape) chip with either top or bottom emission (with the light output and brightness shown in italics for a top emitter and non-italics for a bottom emitter). Row C shows a sapphire substrate chip with a bottom emitter.

As the footprint of mini-dome 142 (denoted as “size” in the table of FIG. 14) is increased, the following effect on the lamp performance has been observed both experimentally in Top-Emitting SMD lamps fabricated using the HRI encapsulant and in Ray-Tracing optical simulations: for footprint dimensions smaller than the die/chip size, the WPE and Light-output is not enhanced and the brightness (lumens or watts per unit solid-angle) measured along the optical-axis of the lamp is increased slightly, compared to a concave lens w/o mini-dome. At these footprint dimensions of the “Mini-dome”, the desirable wide-angle emission characteristic of the Top-Emitting SMD lamp is still maintained. This is also indicative of the tolerance of the lamp performance characteristics with respect to the unintentional introduction of mini-dome shaped aberration in the nominally concave-shape lens during lamp fabrication.

For footprint dimensions larger than the die/chip size, the WPE & Light-output is enhanced but the brightness (lumens or watt per unit solid-angle) measured along the optical-axis of the lamp is enhanced to a greater extent, compared to a concave lens without mini-dome 142. At these footprint dimensions of mini-dome 142, the lamp acquires a narrower angular emission, resulting in a higher enhancement of the on-axis brightness. This enables the achievement of higher brightness lamps for applications that require narrower angular emission characteristics, and simultaneously satisfying the “Flat-Profile” form-factor requirement. Increasing the footprint dimension of mini-dome 142 results in a monotonic enhancement of the WPE & Light-output, compared to a concave lens without a mini-dome. Increasing the footprint dimension of the mini-dome leads to a higher potential enhancement in the Brightness measured along the optical-axis of the lamp, compared to a concave lens w/o mini-dome.

The tables below the figures, list the effect of the mini-dome form-factor on the WPE and On-Axis Brightness (based on Ray-Tracing simulations for a 300×300 micron dimension AlInGaN die/chip) in a Top-Emitting SMD Lamp with HRI Concave Lens. As seen below, a similar trend is observed across a variety of die/chip geometries (ie. top emitter or bottom emitter; SiC/GaN Iso-Index substrate or sapphire substrate; vertical-sidewalls or sloped side-wall geometrically enhanced shape)

Semi-Hemispherical “Blob” Embodiment

With increased proliferation of Surface Mount Device (SMD) geometry LED lamp packages, the cross-sectional area of the reflective cavity (housing the LED die/chip) is becoming comparable to that of the lamp lens. Commercially available Top-Emitting SMD lamps with a Flat-shaped lens, and SMD Power-LED lamps with a Dome-shaped lens, are a few examples. The cross-sectional area of the lens may be at most ˜2 times the cross-sectional area of the reflective cavity (or smaller).

This is in contrast to the Bullet-Shaped LED lamps described above, where the 5 mm diameter lens has a cross-sectional area which is at least 10 times the cross-sectional area of the 1 mm diameter sized reflective cavity. Similarly, there are other SMD Power-LED lamps with a 6 mm Dome-shaped lens and a reflective cavity with ˜2.5 mm diameter. Thus, for the geometries considered for the purpose of this invention, the reflective cavity does not approximate an optical point-source in comparison to the lens.

This embodiment demonstrates that the maximum enhancement in Light Extraction Efficiency (LEE) and thus the Wall Plug Efficiency (WPE) & Optical Power, is obtained when:
1) The die/chip (and submount) are encapsulated by a HRI encapsulant (RI>1.7) “Blob” with a semi-hemispherical form-factor. The “Blob” need not be perfectly hemispherical (but is preferably spherically convex)
2) The HRI “Blob” is contained within the reflective-cavity
3) The HRI “Blob” is not in contact with the sidewall of the reflective cavity.
4) The remainder of the reflective cavity is filled with a RI˜1.5 conventional encapsulant
5) The lamp package may or may not contain a pre-fabricated RI˜1.5 Dome-shaped lens, with the remainder of the volume (with the exception of the HRI “Blob”) being filled with RI˜1.5 conventional encapsulant.
6) The HRI “Blob” may contain fluorescent material for downconversion of the die/chip emission.
7) The Sidewall of the reflective cavity may be either a specular or diffusive reflective surface.

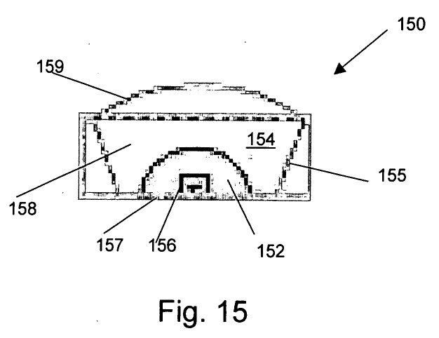

FIG. 15 is a sectional view of a SMD chip 150 with a HRI encapsulant (RI>1.7) “Blob” 152 with a semi-hemispherical form-factor with a spherically convex outer surface mounted within a cavity 154 having sloping reflective walls 155. An LED chip 156 is mounted to the bottom wall 157 of SMD chip 150 and is surrounded by blob 152. The remaining portion of cavity 154 is filled with a conventional encapsulant 158, having a refractive index less than that of HRI blob 152 (for example RI=1.5 or less). A conventional convex lens 159 may optionally be disposed atop chip 150. When view from the top SMD chip 150 is generally square or rectangular in configuration and cavity 154 is circular in top view such that cavity 154 is frusto-conical in overall configuration.

The advantages of the semi-hemispherical HRI “Blob”, compared to a situation where the entire reflective cavity is filled with HRI are:
1) Utilization of less HRI material (For example; 1 uL for a 800 micron semi-hemispherical “Blob” versus 3 uL for a filled reflective-cavity)
2) Higher LEE (For example; WPE enhancement of 46% for a HRI “Blob” versus 27% for a filled reflective cavity with an optimal “Concave” encapsulant shape for RI˜1.7, when compared to RI˜1.5 encapsulant, for a Surface-Emitting SMD lamp)

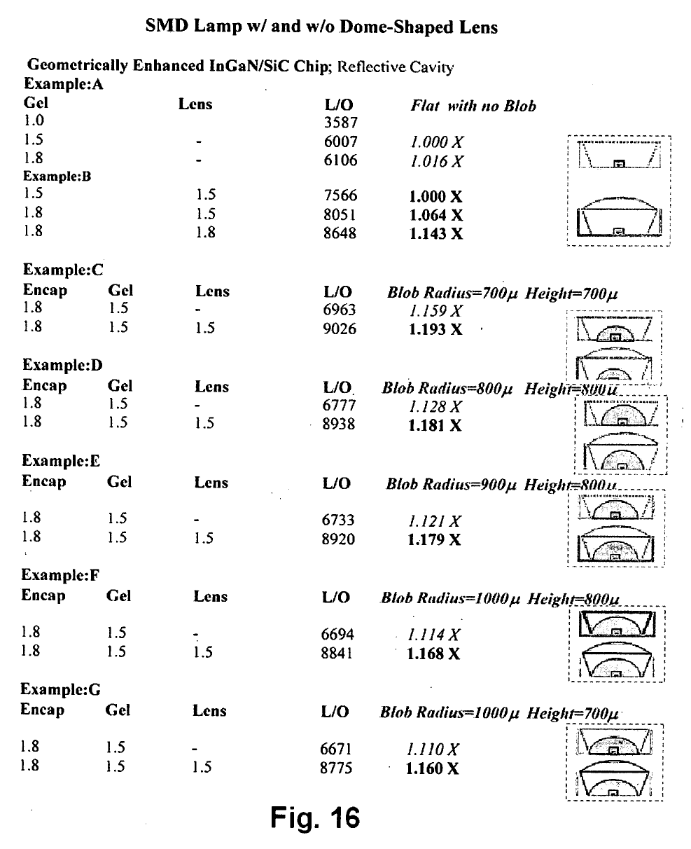

FIG. 16 illustrates in examples A and B a SMD lamp without and with a hemispherical dome-shaped lens but without a semi-hemispherical blob. The reflective cavity is filled with an gel (encapsulating the LED die/chip) optionally followed by the attachment of a pre-fabricated lens in example B with RI˜1.5. Conventionally, a gel with RI˜1.5 is used, and is considered as the “baseline” (with RI˜1.5 Dome lens) with respect to light output “L/O” in arbitrary units. The InGaN/SiC based LED die/chip is disposed in a cavity and has sloping sidewalls. Examples A and B of FIG. 16 shows that replacing the RI˜1.5 gel with a RI˜1.7 gel results in ˜5% enhancement of light output (with RI˜1.5 Dome lens), compared to the baseline (with RI˜1.5 Dome lens).

Examples C through G of FIG. 16 illustrate various sizes (radius of curvature and heights measured in microns) of the semi-hemispherical blob (“Encap”) with and without a dome lens as illustrated in the right hand column which has a RI˜1.7 (“Encap”) with the remaining space in the cavity filled with a “gel” (encapsulant) of RI˜1.5. As is seen, a RI˜1.7 blob encapsulating the die/chip, in conjunction with RI˜1.5 encapsulant or gel filling in the remaining volume, generally results in ˜20% enhancement of light output (with RI˜1.5 Dome lens), compared to the baseline (with RI˜1.5 Dome lens). Note that the blob is not in contact with the sidewall reflector. In this regard note that the smallest semi-hemispherical blob, Example C, provides the highest light output.

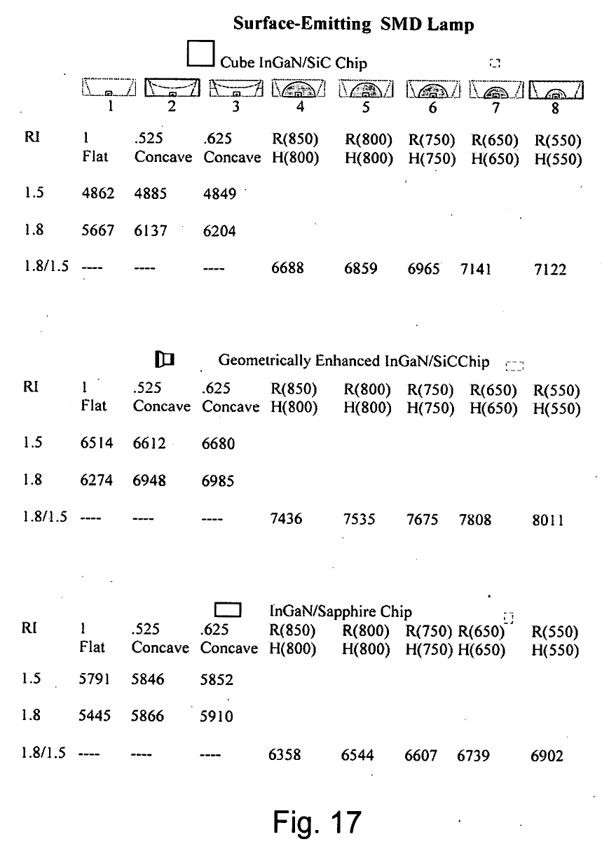

FIG. 17 illustrates varies packaging configurations for Top-Emitting or Surface-Emitting SMD lamps with a flat top (i.e. no convex lens protruding above the package casing). The reflective cavity is filled with an encapsulant (encapsulating the LED die/chip). Row 1 is a flat top configuration, rows 2 and 3 are concave top configurations, as described above and rows 4 through 8 are semi-hemispherical blob configurations. Conventionally, an encapsulant with RI˜1.5 is used, and is considered as the baseline with respect to light output, shown in arbitrary units. InGaN/SiC based LED die/chip with variety of geometries such as “Cube” shaped (top set of numbers) with vertical sidewalls and “Geometrically-Enhanced” truncated-pyramid shaped (middle set of numbers) with sloped sidewalls and InGaN/Sapphire based LED die/chips (bottom set of numbers) were considered.

FIG. 17 shows that for a InGaN/SiC “Cube” die/chip (R.I=2.5), replacing the RI˜1.5 encapsulant with a RI˜1.7 concave shape encapsulant (rows 2 and 3), results in ˜27% enhancement of light output, compared to the baseline (flat shape row 1). However, a RI˜1.7, in conjunction with RI˜1.5 encapsulant filling in the remaining volume (rows 4 through 8), results in ˜45% to 50% enhancement of light output, compared to the baseline. Note that the blob is not in contact with the sidewall reflector. It is also of note that the second smallest semi-hemispherical blob (radius 650 microns, height 650 microns), row 7, provides the highest light output.

FIG. 17 also shows that for a InGaN/SiC Geometrically-Enhanced die/chip (R.I=2.5), replacing the RI˜1.5 encapsulant with a RI˜1.7 concave shape encapsulant (rows 2 and 3), results in only ˜5% enhancement of light output, compared to baseline (with Flat shape row 1). This is a limitation of the RI˜1.7 concave shape lens for this lamp geometry However, a RI˜1.7 blob encapsulating the die/chip, in conjunction with RI˜1.5 encapsulant filling in the remaining volume (rows 4 through 8), results in ˜20% enhancement of light output, compared to baseline. Here the smallest semi-hemispherical blob, row 8, (radius 550 microns, height 550 microns) provides the highest light output.

FIG. 17 shows that for a InGaN/Sapphire die/chip(R.I=2.5), replacing the RI˜1.5 encapsulant with a RI˜1.7 concave shape encapsulant(rows 2 and 3), results in only ˜2% to 8% enhancement of light output, compared to baseline (with flat shape row 1). This is also a limitation of the RI˜1.7 concave shape lens for this lamp geometry. However, a RI˜1.7 “Blob” encapsulating the die/chip, in conjunction with RI˜1.5 encapsulant filling in the remaining volume(rows 4 through 8), results in ˜20% to 30% enhancement of light, compared to the baseline. Here again the smallest semi-hemispherical blob, row 8 (radius 550 microns, height 550 microns), provides the highest light output

Thus, for a Surface-Emitting SMD Lamp, RI˜1.7 a semi-hemispherical blob enables:
1) Attainment of light output enhancement, across a wider variety of LED die/chip geometries
2) Attainment of light output enhancement level, comparable to that achieved in Bullet-shaped LED lamps.
3) Smaller semi-hemispherical blobs are generally more efficient than larger ones

The invention has been described with respect to preferred embodiments. However, as those skilled in the art will recognize, modifications and variations in the specific details which have been described and illustrated may be resorted to without departing from the spirit and scope of the invention as defined in the appended claims.

What is claimed is:

1. An LED lamp comprising:
a) an LED chip;
b) a reflective cavity containing the LED chip;
c) a high refractive index material, with a refractive index greater than or equal to 1.7, encapsulating the LED chip and contained inside the reflective cavity; and
d) a dome-shaped lens with a refractive index smaller than that of the HRI material, the dome shaped lens having an outer surface that is convex an inner surface facing the LED die/chip.

2. The LED lamp as claimed in claim 1 further including an optical gel material with a RI smaller than that of the HRI encapsulant but at least equal to that of the lens, disposed between the HRI encapsulant and the inner surface of the dome-shaped lens.

3. The LED lamp as claimed in claim 1 further including a fluorescent material to obtain lamp emission at wavelengths different from those comprising the LED chip emission.

4. The LED lamp as claimed in claim 1, wherein the walls of the reflective cavity are specularly reflective.

5. The LED lamp as claimed in claim 1, wherein the walls of the reflective cavity are diffusively reflective.

6. The LED lamp as claimed in claim 1 wherein the encapsulant includes a fluorescent material to obtain lamp emission at wavelengths different from those comprising the LED chip emission.

7. The LED lamp as claimed in claim 6 wherein the fluorescent material comprises nanophosphors.

8. The LED lamp as claimed in claim 1 wherein the high refractive index material has an outer surface that is concave.

9. The LED lamp as claimed in claim 1 wherein the high refractive index material has an outer surface that is convex.

10. The LED lamp as claimed in claim 1 wherein the high refractive index material has an outer surface that is flat.

11. A packaging configuration for a device that emits light, comprising:
a) a device that emits light;
b) an encapsulant surrounding said light emitting device, said encapsulant being substantially transparent to the light emitted by said light emitting device, said encapsulant having a refractive index of 1.7 or greater; and
c) the encapsulant being configured so that its upper surface is concave.

12. The configuration as claimed in claim 11, wherein the light emitting device is an LED.

13. The configuration as claimed in claim 11, wherein the LED emits monochromatic light.

14. The configuration as claimed in claim 11, wherein the light emitting device is disposed in a cup having reflective side walls and a base with the encapsulant being disposed in the cup.

15. The configuration as claimed in claim 14, wherein the cup is part of a surface mount device.

16. The configuration as claimed in claim 14, wherein the walls of the cup are specularly reflective.

17. The configuration as claimed in claim 14, wherein the walls of the cup are diffusively reflective.

18. The configuration as claimed in claim 11, wherein the encapsulant contains light emitting nanoparticles.

19. The configuration as claimed in claim 11, wherein the concave upper surface of the encapsulant includes a small dome shaped lens disposed proximate to the light emitting device.

20. In a surface mount device having a cup, an LED mounted within the cup and an a transparent encapsulant surrounding the LED the improvement comprising the encapsulant having a refractive index of 1.7 or greater.

21. The surface mount device as claimed in claim 20, wherein the encapsulant has an upper surface that is flat.

22. The surface mount device as claimed in claim 20, wherein the encapsulant has an upper surface that is concave.

23. The surface mount device as claimed in claim 22, wherein the concave upper surface of the encapsulant includes a small dome shaped lens disposed proximate to the LED.

24. The surface mount device as claimed in claim 20, wherein the walls of the cup are specularly reflective.

25. The surface mount device as claimed in claim 20, wherein the walls of the cup are diffusively reflective.

26. The surface mount device as claimed in claim 20, wherein the encapsulant contains light emitting particles.

27. The surface mount device as claimed in claim 20, wherein the encapsulant contains nanoparticles.

28. A packaging configuration for a device that emits light, comprising:
a) a cavity containing reflective walls;
b) a device that emits light, mounted within said cavity;
c) an encapsulant having a refractive index of 1.7 or greater surrounding said light emitting device, said encapsulant being substantially transparent to the light emitted by said light emitting device, said encapsulant having a convex surface; and
c) a material having a refractive index of less than of the encapsulant surrounding the encapsulant and at least partially filling said cavity.

29. The configuration as claimed in claim 28, wherein the light emitting device is an LED.

30. The configuration as claimed in claim 28, wherein the cavity is part of a surface mount device
